(19) United States
(12) Patent Application Publication
(10) Pub. No.: US 2019/0237356 A1
(43) Pub. Date: Aug. 1, 2019

(54) AIR GAP FORMATION IN BACK-END-OF-LINE STRUCTURES

(71) Applicant: GLOBALFOUNDRIES Inc., Grand Cayman (KY)

(72) Inventors: Ravi Prakash Srivastava, Clifton Park, NY (US); Sunil K. Singh, Mechanicville, NY (US)

(21) Appl. No.: 15/882,465

(22) Filed: Jan. 29, 2018

(51) Int. Cl. H01L 21/768; H01L 23/528; H01L 23/532; H01L 21/311; H01L 23/522

(52) U.S. Cl. CPC H01L 21/7682; H01L 23/528; H01L 23/53295; H01L 21/76834; H01L 21/76802; H01L 21/0276; H01L 21/76825; H01L 21/31144; H01L 23/5226; H01L 21/76828; H01L 21/31116; H01L 21/76877

(57) ABSTRACT

Interconnect structures and methods for forming an interconnect structure. A dielectric layer of a metallization level is deposited and a trench is patterned in the dielectric layer. A sacrificial layer is formed in the trench in the dielectric layer. The sacrificial layer is patterned to form a first trench and a second trench separated from the first trench by a section of the sacrificial layer. A first metal interconnect is formed in the first trench, a second metal interconnect is formed in the second trench, and a porous cap layer is formed over the first metal interconnect, the second metal interconnect, and the section of the sacrificial layer. After forming the porous cap layer, the section of the sacrificial layer is removed.

### BACKGROUND

The present invention relates to semiconductor device fabrication and integrated circuits and, more specifically, to interconnect structures and methods for forming an interconnect structure.

An interconnect structure may be used to electrically connect device structures fabricated by front-end-of-line (FEOL) processing. A back-end-of-line (BEOL) portion of the interconnect structure may include metallization formed using a damascene process in which via openings and trenches etching in a dielectric layer are filled with metal to create features of a metallization level. The dielectric layer may be formed from low-k dielectric materials that provide a reduced capacitance, but such reduced-capacitance dielectric layers are also required to provide a high level of performance.

Improved interconnect structures and methods for forming an interconnect structure are needed.

### SUMMARY

In an embodiment of the invention, an interconnect structure includes a metallization level with a dielectric layer, a first metal interconnect, a second metal interconnect, and an air gap between the first metal interconnect and the second metal interconnect. The structure further includes a cap layer over the metallization level. The cap layer has a planar surface above the air gap.

In an embodiment of the invention, a method of forming an interconnect structure includes depositing a dielectric layer of a metallization level, patterning a trench in the dielectric layer, and forming a sacrificial layer in the trench in the dielectric layer. The method further includes patterning the sacrificial layer to form a first trench and a second trench separated from the first trench by a section of the sacrificial layer. A first metal interconnect is formed in the first trench, a second metal interconnect is formed in the second trench, and a porous cap layer is formed over the first metal interconnect, the second metal interconnect, and the section of the sacrificial layer. After forming the porous cap layer, the section of the sacrificial layer is removed.

In an embodiment of the invention, a method of forming an interconnect structure includes depositing a dielectric layer of a metallization level, patterning the dielectric layer to form a first trench, and forming a section of a sacrificial layer in the first trench. After forming the sacrificial layer, the dielectric layer is patterned to form a second trench and a third trench separated from the second trench by the section of the sacrificial layer in the first trench. A first metal interconnect is formed in the first trench, a second metal interconnect is formed in the second trench, and a porous cap layer is formed over the first metal interconnect, the second metal interconnect, and the section of the sacrificial layer. After forming the porous cap layer, the section of the sacrificial layer is removed.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIGS. 1-9 are cross-sectional views of an interconnect structure at successive fabrication stages of a processing method in accordance with embodiments of the invention.

FIGS. 10-15 are cross-sectional views of an interconnect structure at successive fabrication stages of a processing method in accordance with embodiments of the invention.

### DETAILED DESCRIPTION

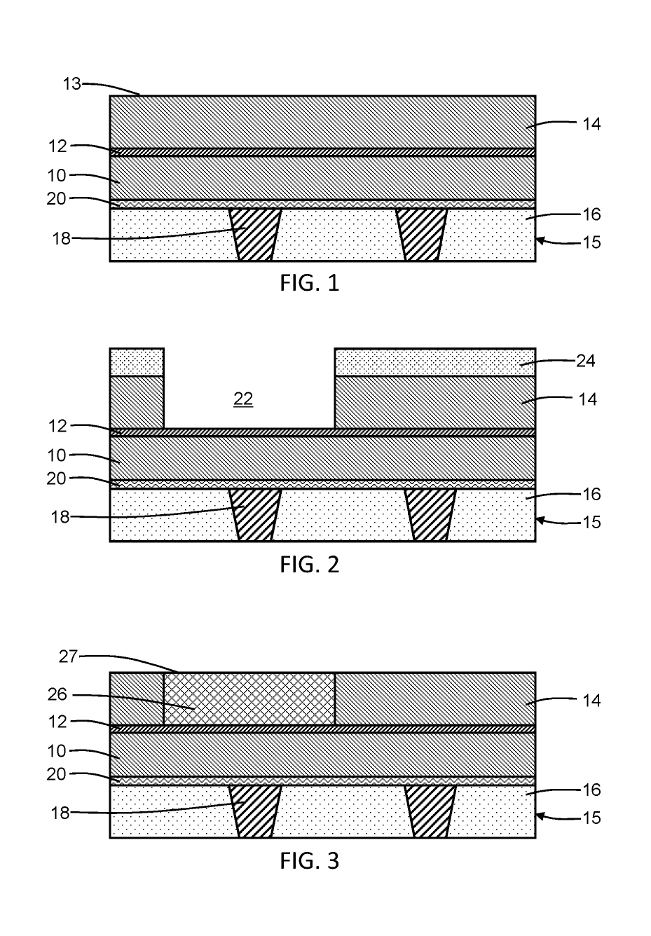

With reference to FIG. 1 and in accordance with embodiments of the invention, dielectric layers 10, 12, 14 are formed in a layer stack over a metallization level 15 that is formed by back-end-of-line (BEOL) processing. The metallization level 15 includes a dielectric layer 16 and metal interconnects 18 embedded in the dielectric layer 16. An etch stop layer 20 is arranged between the dielectric layer 10 and the metallization level 15. The metallization level 15 is arranged over a substrate (not shown) that includes device structures formed by front-end-of-line (FEOL) processing. In an embodiment, the dielectric layer 10 and the dielectric layer 14 may have equal thicknesses.

The dielectric layers 10, 14 may be composed of an electrical insulator, such as a low-k dielectric material or an ultra-low-k (ULK) dielectric material having a dielectric constant that may have a dielectric constant in a range of 2.2 to 2.6 after curing. In an embodiment, the dielectric layers 10, 14 may be composed of a doped oxide of silicon. The dielectric layers 10, 14 may contain a concentration of a porogen that can be activated by curing to form pores in a solid matrix of dielectric material. The porogen is a sacrificial organic-based material in the form of particles that are distributed in the solid matrix of dielectric material and that are used to generate or form pores in the solid matrix when the dielectric layers 10, 14 are cured. The porosity of the dielectric layers 10, 14, following curing, may be adjusted by adjusting the concentration of porogen in the matrix.

The dielectric layer 12, which is arranged in the vertical direction between the dielectric layer 10 and the dielectric layer 14 in the layer stack, may be composed of a dielectric material that etches selective to the dielectric material of the dielectric layer 14. The dielectric layer 12, which is thinner than either the dielectric layer 10 or the dielectric layer 14, operates as an etch stop layer during subsequent processing. The dielectric layer 12 may be composed of an oxide of silicon that has a lower doping concentration than the dielectric layer 10 and the dielectric layer 14 such that the resulting layer stack has a graded composition.

With reference to FIG. 2 in which like reference numerals refer to like features in FIG. 1 and at a subsequent fabrication stage, a trench 22 is formed in the dielectric layer 14 by lithography and etching. To that end, an etch mask 24 is formed by lithography over the dielectric layer 14. The etch mask 24 may include, for example, a bottom anti-reflective coating (BARC) layer, a spin-on hardmask, and/or a photoresist layer comprised of a photoresist material that is applied by a spin coating process, pre-baked, exposed to a radiation projected through a photomask, baked after exposure, and developed with a chemical developer to form an opening at the intended location in the dielectric layer 14 for the trench 22. The etching process may be a reactive ion etching (RIE) process that stops on the material of the dielectric layer 12, which controls and defines the depth of the trench 22.

With reference to FIG. 3 in which like reference numerals refer to like features in FIG. 2 and at a subsequent fabrication stage, a sacrificial layer 26 is applied that fills the trench 22 in the dielectric layer 14. The sacrificial layer 26 may be composed of an energy removal film material and, in an embodiment, may be composed of an organic (CxHyOz) compound, such as a silicon-based organic compound that is deposited by, for example, plasma-enhanced chemical vapor deposition (PE-CVD) or a spin-on process. In an embodiment, the energy removal film material constituting the sacrificial layer 26 may be comprised of a porogen material, which is a sacrificial organic-based material that is converted from a solid state to a gaseous state when treated with heat energy and/or electromagnetic radiation. The sacrificial layer 26 may be etched back or polished following formation to have a top surface 27 that is coplanar with a top surface 13 of the dielectric layer 14. The trench 22 and sacrificial layer 26 in the trench 22 define a selected region of the dielectric layer 14 for the subsequent formation of air gaps.

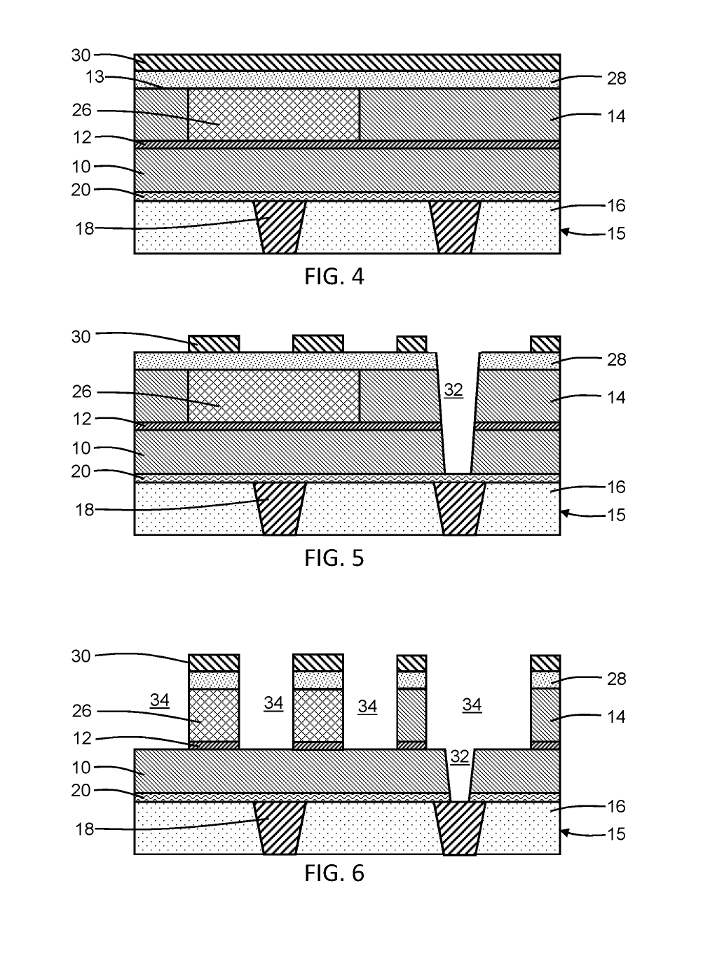

With reference to FIG. 4 in which like reference numerals refer to like features in FIG. 3 and at a subsequent fabrication stage, a dielectric hardmask layer 28 is formed over the top surface 13 of the dielectric layer 14 and the top surface 27 of the sacrificial layer 26. The dielectric hardmask layer 28 may be comprised of a dielectric material, such as a nitride of silicon like SiON, deposited by chemical vapor deposition (CVD). The material constituting the dielectric hardmask layer 28 is chosen to be removable from the dielectric layer 14 selective to the material of the dielectric layer 14.

A metal hardmask layer 30 is formed over the dielectric hardmask layer 28. The metal hardmask layer 30 may be comprised of, for example, titanium nitride (TiN) deposited by physical vapor deposition (PVD). The metal hardmask layer 30 is removable from the dielectric hardmask layer 28 selective to the material of the dielectric hardmask layer 28.

With reference to FIG. 5 in which like reference numerals refer to like features in FIG. 4 and at a subsequent fabrication stage, the metal hardmask layer 30 is patterned with lithography and etching to form openings for the subsequent formation of trenches in the dielectric layer 14 and the sacrificial layer 26. The dielectric hardmask layer 28 is patterned with lithography and etching to form an opening in the dielectric hardmask layer 28, following by the patterning of a via opening 32 in the dielectric layers 10, 12, 14 stopping on the etch stop layer 20. The etching process, which may be a reactive-ion etching (ME) process, may be conducted in a single etching step or multiple etching steps with different etch chemistries. The via opening 32 penetrates through the dielectric layers 10, 12, 14 to one of the metal interconnects 18 in the metallization level 15. The portion of the dielectric layer 10 in the air gap region lacks via openings.

With reference to FIG. 6 in which like reference numerals refer to like features in FIG. 5 and at a subsequent fabrication stage, trenches 34 are formed in the dielectric layer 12 and in the sacrificial layer 26 with an etching process, and the etch stop layer 20 is removed at the bottom of the via opening 32 with an etching process. The etching processes, which may be a reactive-ion etching (RIE) processes, may be conducted in a single etching step or multiple etching steps with different etch chemistries, and relies on the patterned metal hardmask 30 to define the locations of the trenches 34.

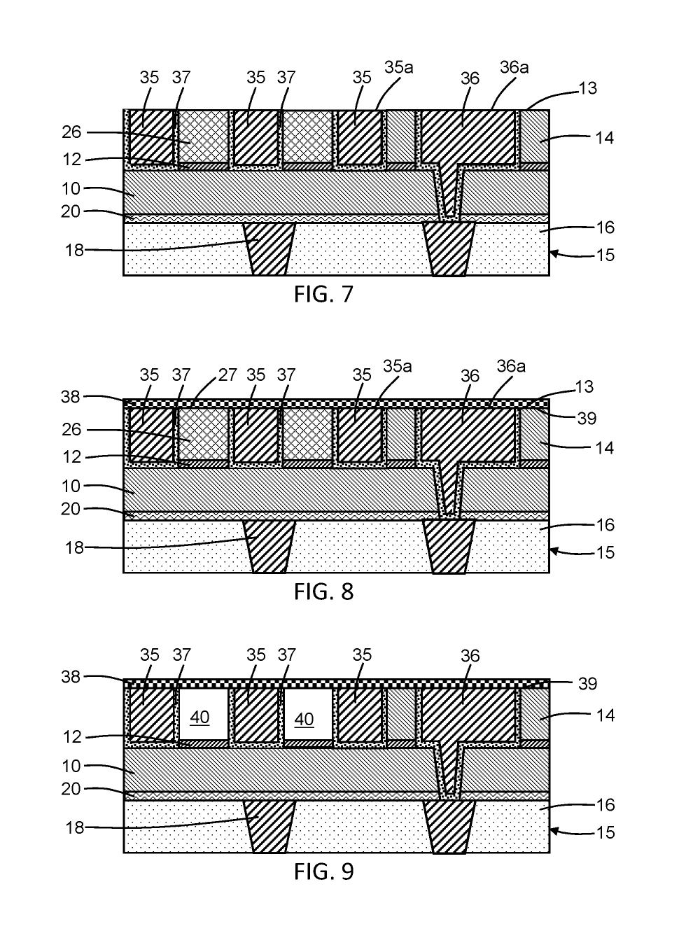

With reference to FIG. 7 in which like reference numerals refer to like features in FIG. 6 and at a subsequent fabrication stage, the hardmask layers 28, 30 are removed, and the via opening 32 and trenches 34 are filled with a conductor to complete the dual-damascene process to form metal interconnects 35, 36. The metal interconnects 35 are arranged in the trenches 34 that lack adjoined via openings. The metal interconnect 36 is arranged in the adjoined via opening 32 and trench 34, and is connected with the metal interconnect 18 in the metallization level 15 that is arranged at the bottom of the via opening 32. The metal interconnect 36 includes a wire arranged in the dielectric layer 10, as well as a via that is arranged in the dielectric layer 10 and seamlessly joined with the wire. Portions of the sacrificial layer 26 fill the spaces between the metal interconnects 35 that are located in the trenches 34. The portion of the dielectric layer 10 in the air gap region does not include vias.

The metal interconnects 35, 36 may be sections of a conductor layer that is deposited to fill the via opening 32 and the trenches 34 after a liner layer 37 is applied as a coating. The conductor layer may be composed of a metal, such as copper (Cu), cobalt (Co), ruthenium (Ru), or rhenium (Re) that is deposited by electroless or electrolytic deposition. The liner layer 37 may be composed of one or more conductive materials (i.e., conductors), such as titanium nitride (TiN), tantalum nitride (TaN), tantalum (Ta), titanium (Ti), tungsten (W), tungsten nitride (WN), ruthenium (Ru), rhenium (Re), a layered stack of these conductive materials (e.g., a bilayer of Ti and TiN), or a combination of these conductive materials, deposited by, for example, physical vapor deposition (PVD) or chemical vapor deposition (CVD). The respective materials of the liner layer 37 and the conductor layer also deposit in the field area on the top surface 13 of the dielectric layer 14 and the top surface 27 of the sacrificial layer 26, and may be removed from the field area with a chemical mechanical polishing (CMP) process, which results in respective top surfaces 35a, 36a for the metal interconnects 35, 36 that are coplanar with the top surface 13 of the dielectric layer 14 and the top surface 27 of the sacrificial layer 26.

With reference to FIG. 8 in which like reference numerals refer to like features in FIG. 7 and at a subsequent fabrication stage, a cap layer 38 is formed over the top surface 13 of the dielectric layer 14, the top surface 27 of the sacrificial layer 26, the top surfaces 35a of the metal interconnects 35, and the top surface 36a of the metal interconnect 36. The material of the cap layer 38 permits gas permeation and diffusion across its thickness and, in an embodiment, has a degree of porosity that permits gas permeation and diffusion across its thickness. In an embodiment, the cap layer 38 may be composed of a porous dielectric material, such as a nitrogen-doped silicon carbide (e.g., NBloK).

The cap layer 38 has a bottom surface 39 that directly contacts the top surface 13 of the dielectric layer 14, the top surface 27 of the sections of the sacrificial layer 26, and the top surfaces 35a, 36a of the metal interconnects 35, 36. The bottom surface 39 of the cap layer 38 is constrained by the contacting relationship with these coplanar top surfaces 13, 17, 35a, 36a to be planar. The top surface of the cap layer 38 opposite to the bottom surface 39 may also be planar. Because of the contacting relationship, the bottom surface 39 of the cap layer 38 lacks indents be characteristic of the pinch-off that occurs in conventional air gap formation processes and that would otherwise interrupt the bottom surface planarity.

With reference to FIG. 9 in which like reference numerals refer to like features in FIG. 8 and at a subsequent fabrication stage, after forming the cap layer 38, the dielectric material of the dielectric layers 10, 14 may be cured to activate the porogen and generate pores inside the solid matrix of the dielectric layers 10, 14 such that the respective constituent dielectric materials become porous. The dielectric material of the dielectric layers 10, 14 may be cured thermally at a temperature in a range of 100° C. to 600° C. over a given time (i.e., longer times for lower temperatures) determined to convert the majority of the distributed porogen to distributed pores. In an embodiment, the curing process may combine thermal treatment heating the dielectric layers 10, 14 with radiation exposure, such as exposure to radiation in the ultraviolet (UV) range of the electromagnetic spectrum. For example, thermal treatment may be performed at a temperature of 400° C. and may include continuous or intermittent exposure to ultraviolet (UV) radiation during heating.

The energy removal film material contained in the sections of the sacrificial layer 26 is also modified by an activation treatment to remove the sections of the sacrificial layer and thereby form air gaps 40. In an embodiment, the curing of the dielectric material of the dielectric layers 10, 14 may represent the activation treatment causing the energy removal film material to decompose into a gaseous state, which may be released to the ambient environment through the porous dielectric material of the cap layer 38. The utilization of the sacrificial layer 26 and the formation of the trenches 34 for the metal interconnects 35 in the sacrificial layer 26 provide further control over the dimensions and profile of the air gaps 40.

The air gaps 40 may be characterized by a permittivity or dielectric constant of near unity (i.e., vacuum permittivity). The air gaps 40 may be filled by atmospheric air at or near atmospheric pressure, may be filled by another gas (e.g., the gas resulting from the decomposition of the energy removal film) at or near atmospheric pressure, or may contain atmospheric air or another gas at a sub-atmospheric pressure (e.g., a partial vacuum).

In an alternative embodiment, the activation treatment used to form the air gaps 40 may be performed independent of, or in addition to, the curing process applied to treat the dielectric layers 10, 14. For example, the dielectric layers 10, 14 may lack a porogen concentration and may therefore not require a curing step to generate porosity.

The dielectric layers 10, 12, 14, metal interconnects 35, 36, air gaps 40, and cap layer 38 collectively form a metallization level that is arranged in the BEOL interconnect structure over the metallization level 15. BEOL processing may continue to form additional metallization levels over the cap layer 38.

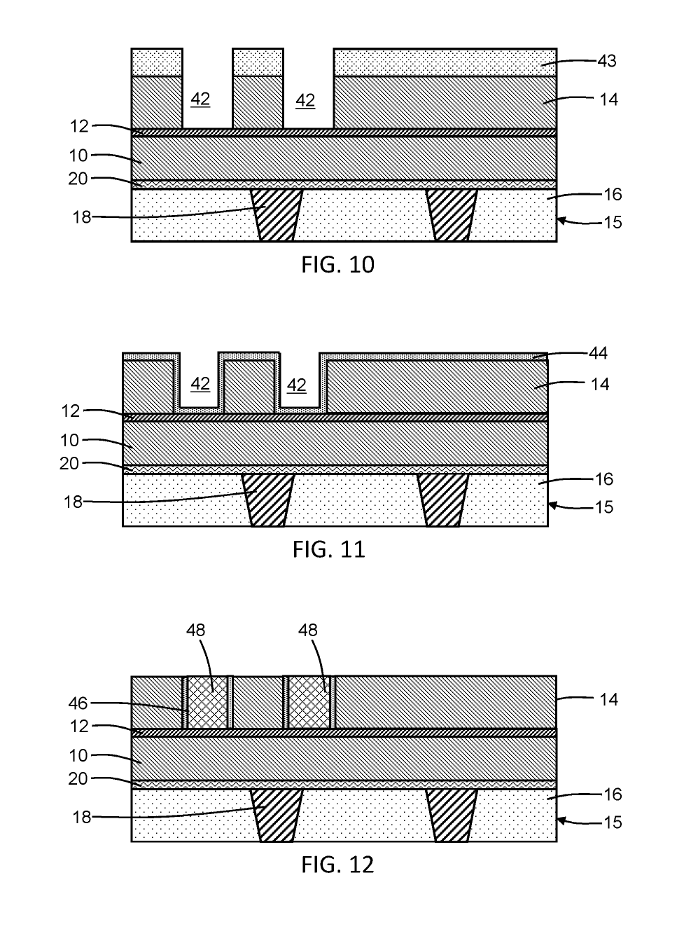

With reference to FIG. 10 in which like reference numerals refer to like features in FIG. 1 and in accordance with alternative embodiments, trenches 42 are formed in the dielectric layer 14 by lithography and etching. An etch mask 43 is formed by lithography over the dielectric layer 14. The etch mask 43 may include, for example, a bottom anti-reflective coating (BARC) layer, a spin-on hard mask, and/or a photoresist layer comprised of a photoresist material that is applied by a spin coating process, pre-baked, exposed to a radiation projected through a photomask, baked after exposure, and developed with a chemical developer to form an opening at the intended location in the dielectric layer 14 for the trenches 42. The etching process may be a reactive ion etching (RIE) process that stops on the material of the dielectric layer 12, which controls and defines the depth of the trenches 42. The location of the trenches 42 defines an air gap region.

With reference to FIG. 11 in which like reference numerals refer to like features in FIG. 10 and at a subsequent fabrication stage, a conformal layer 44 is formed as a liner that covers the top surface 13 of the dielectric layer 14, the sidewalls of the trenches 42, and an area of the dielectric layer 12 exposed at the bottom of each of the trenches 42. In an embodiment, the conformal layer 44 may be comprised of a dielectric material, such as an oxide of silicon (e.g., silicon dioxide (SiO₂)) or a nitride of silicon (e.g., silicon nitride (Si₃N₄)), that can be etched selectively to the material of the dielectric layer 14.

With reference to FIG. 12 in which like reference numerals refer to like features in FIG. 11 and at a subsequent fabrication stage, spacers 46 that are formed from the material of the conformal layer 44 using a directional etch process, such as reactive ion etching (RIE). The spacers 46 represent vertical sections of the conformal layer 44 arranged adjacent to the sidewalls of the trenches 42, and the conformal layer 44 is removed from the top surface of the dielectric layer 14 and the areas of the dielectric layer 12 at the bottom of the trenches 42.

Sections of a sacrificial layer 48 are formed between the spacers 46 in the trenches 42. The sacrificial layer 48 may be formed from the same material as the sacrificial layer 26 (FIG. 3) and form in the same manner as the sacrificial layer 26.

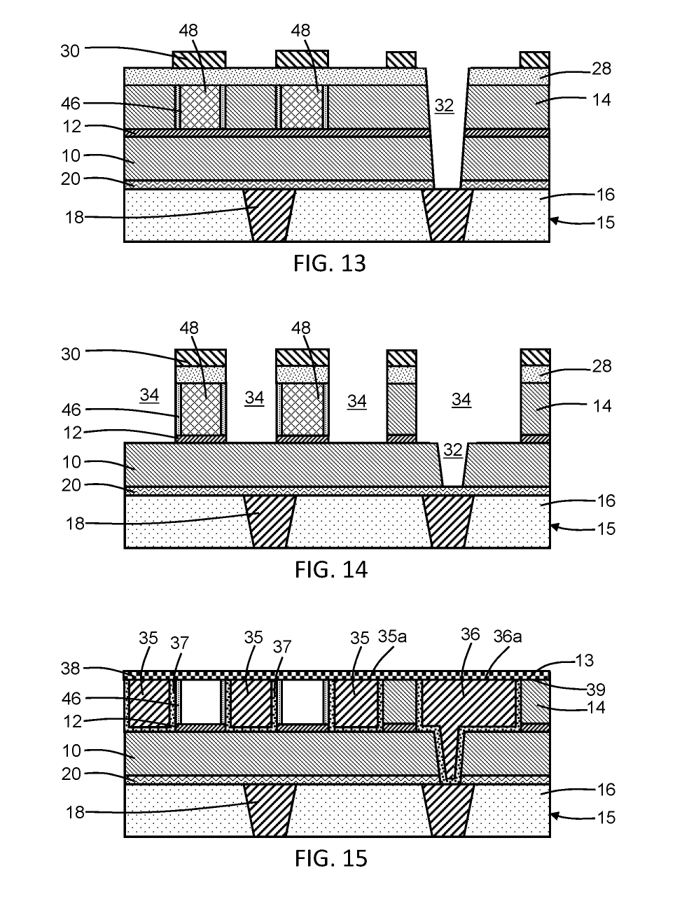

With reference to FIG. 13 in which like reference numerals refer to like features in FIG. 12 and at a subsequent fabrication stage, the dielectric hardmask layer 28 and metal hardmask layer 30 are sequentially applied over the top surface 27 of the sections of the sacrificial layer 48 and the top surface 13 of the dielectric layer 14. The metal hardmask layer 30 is patterned with lithography and etching to form openings for the subsequent formation of trenches in the dielectric layer 14 and the sacrificial layer 26. The patterned metal hardmask layer 30 is a reverse mask of the etch mask 43, which results in the subsequently patterned trenches being arranged horizontally relative to the sets of sections of the sacrificial layer 48 and spacers 46. The dielectric hardmask layer 28 is patterned with lithography and etching to form an opening in the dielectric hardmask layer 28, following by the patterning of the via opening 32 in the dielectric layers 10, 12, 14 stopping on the etch stop layer 20. The etching process, which may be a reactive-ion etching (ME) process, may be conducted in a single etching step or multiple etching steps with different etch chemistries.

With reference to FIG. 14 in which like reference numerals refer to like features in FIG. 13 and at a subsequent fabrication stage, the trenches 34 are formed in the dielectric layer 14, the etch stop layer 20 is removed at the bottom of the via opening 32, and the dielectric layer 12 is removed at the bottom of the trenches 34. To that end, an etching process, which may be a reactive-ion etching (ME) process, may be conducted in a single etching step or multiple etching steps with different etch chemistries, and may rely on the patterned metal hardmask layer 30 to define the locations of the trenches 34.

With reference to FIG. 15 in which like reference numerals refer to like features in FIG. 14 and at a subsequent fabrication stage, the process flow continues as described in FIGS. 7-9 to form the metal interconnects 35, 36, to form the cap layer 38 with the bottom surface 39 that directly contacts the top surface 13 of the dielectric layer 14, the top surface 27 of the sections of the sacrificial layer 26, the top surface 35a of the metal interconnects 35, and the top surface 36a of the metal interconnect 36, and to remove the sacrificial layer 26 by the activation treatment to form the air gaps 40 arranged between the metal interconnects 35. The spacers 46, which indirectly contact the metal interconnects 35, 36, are arranged horizontally between the air gaps 40 and the metal interconnects 35.

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

References herein to terms such as “vertical”, “horizontal”, “lateral”, etc. are made by way of example, and not by way of limitation, to establish a frame of reference. Terms such as “horizontal” and “lateral” refer to a direction in a plane parallel to a top surface of a semiconductor substrate, regardless of its actual three-dimensional spatial orientation. Terms such as “vertical” and “normal” refer to a direction perpendicular to the “horizontal” and “lateral” direction. Terms such as “above” and “below” indicate positioning of elements or structures relative to each other and/or to the top surface of the semiconductor substrate as opposed to relative elevation.

A feature “connected” or “coupled” to or with another element may be directly connected or coupled to the other element or, instead, one or more intervening elements may be present. A feature may be “directly connected” or “directly coupled” to another element if intervening elements are absent. A feature may be “indirectly connected” or “indirectly coupled” to another element if at least one intervening element is present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. An interconnect structure comprising:
a metallization level including a first dielectric layer, a first metal interconnect, a second metal interconnect, and an air gap in a portion of a trench horizontally between the first metal interconnect and the second metal interconnect;
a second dielectric layer arranged at a bottom of the trench;
a first dielectric spacer arranged adjacent to a first sidewall of the trench between the first metal interconnect and the air gap, the first dielectric spacer extending in a vertical direction relative to the second dielectric layer;
a second dielectric spacer arranged adjacent to a second sidewall of the trench between the second metal interconnect and the air gap, the second dielectric spacer extending in a vertical direction relative to the second dielectric layer; and
a cap layer over the metallization level, the cap layer having a planar surface above the air gap, the first metal interconnect, and the second metal interconnect,
wherein the planar surface of the cap layer is in direct contact with the first metal interconnect and the second metal interconnect.

2-3. (canceled)

4. The interconnect structure of claim 1 wherein the first spacer has a contacting relationship with a sidewall of the first metal interconnect, and the second spacer has a contacting relationship with a sidewall of the second metal interconnect.

5. The interconnect structure of claim 1 wherein the cap layer is comprised of a porous dielectric material.

6. (canceled)

7. The interconnect structure of claim 1 wherein the metallization level includes a second air gap, and the first metal interconnect is arranged between the first air gap and the second air gap.

8. The interconnect structure of claim 1 wherein the first dielectric layer is arranged over an etch stop layer, the etch stop layer is arranged over a third dielectric layer, the first dielectric layer is composed of a first dielectric material, the etch stop layer is composed of a second dielectric material, and the first dielectric material can be selectively etched relative to the second dielectric material.

9-20. (canceled)

21. The interconnect structure of claim 1 wherein the metallization level includes a third interconnect arranged in the first dielectric layer, the first dielectric layer is comprised of an oxide of silicon, and the second dielectric layer is comprised of an oxide of silicon that has a lower doping concentration than the first dielectric layer.

22. The interconnect structure of claim 5 wherein the porous dielectric material is nitrogen-doped silicon carbide.
